(19) United States
(12) Patent Application Publication
(10) Pub. No.: US 2006/0256537 A1
(43) Pub. Date: Nov. 16, 2006

(54) Printed circuit board and producing method for the same

(75) Inventor: Seisuke Muroki, Saitama (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/429,211

(22) Filed: May 8, 2006

(30) Foreign Application Priority Data
May 16, 2005 (JP) 2005-143058

(51) Int. Cl. H05K 1/14

(52) U.S. Cl. 361/739

(57) ABSTRACT

A thermal transfer printer is used for printing colored patterns on a flexible material. A conductive-color-ink ribbon contains inks of cyan, magenta and yellow in which conductive powders are added. The colored pattern formed by using this ink ribbon has conductivity. The colored patterns are separated by color every pattern through which an identical circuit signal is carried. As to the color-coded patterns, it is possible to distinguish the pattern through which another circuit signal is carried. An FPC comprising the color-coded patterns has high pattern-visibility so that it is possible to prevent improper connection or the like from occurring.

### FIELD OF THE INVENTION

The present invention relates to a printed circuit board having a colored pattern formed by a color printer, and further relates to a producing method for the printed circuit board.

### BACKGROUND OF THE INVENTION

A conductor for forming an electronic circuit is formed on a printed circuit board. The conductor is composed of pads, lands and wiring patterns. A semiconductor device package of an IC and so forth is fixed to the pads. Moreover, electronic parts of a resistor, a capacitor and so forth are also fixed to the pads. The land is a connection area for performing wiring on both surfaces of a substrate and for performing wiring in each layer of a multi-layer substrate. The wiring pattern connects a lead of the respective parts, the pads and the lands.

Regarding the printed circuit board (hereinafter referred to as PCB) having the conductor, it is required to satisfy various conditions concerning electrical insulation, heat resistance, moisture resistance, dimensional stability, processability for punching a through hole, low price and so forth. Some PCBs widely utilized as the suitable PCB for the above requirement employ a glass fabric and a glass board material including epoxy resin. Another widely utilized PCB employs a kraft paper including phenol resin. Meanwhile, a flexible printed circuit board (hereinafter referred to as FPC) is used when a containing space therefor is small. As a substrate of the FPC, a polyimide film is utilized in general. Heat resistance of the polyimide film is high and a coefficient of thermal expansion thereof is adjustable. Thus, there are advantages concerning multilayer wiring, high-density package of parts, countermeasures against high heating and thermal dimensional stability, and so forth.

In the meantime, methods for forming the electronic circuit on the substrate are roughly divided into a subtractive method and an additive method. In the subtractive method, a resist pattern is formed, and then exposed copper-foil portions are dissolved and removed by chemicals. Lastly, an oxide film is removed to expose circuit portions of conductors. By contrast, in the additive method, a plating resist pattern is formed and copper plating is performed for only circuit portions of the conductors. In recent years, a screen printing method is widely used as one of the additive method. In the screen printing method, a metallic mesh screen produced by means of photolithography is placed on a substrate and conductive paste is applied through the mesh screen by using a squeeze.

In a step for producing the above-mentioned circuit board, it is troublesome and expensive to form a copper-foil pattern and to perform an attachment operation of a base and a cover lay. Meanwhile, if specification of a new circuit board is changed in the middle of the design thereof, development process of the circuit board is delayed. The delay of the development process causes a heavy burden to a supplier of the circuit board, who must supply the product to the market more quickly relative to competitors. In view of this, some methods for producing the circuit board are proposed for the purposes of shortening a producing period in comparison with the conventional method, and of lowering the production cost, and of making countermeasure against the change of the specification easy. For instance, there is a method in which conductive paste is used for forming an electronic circuit on a substrate with an ink-jet printer (see Japanese Patent Laid-Open Publication No. 2004-186630). There is another method in which an ink ribbon composed of a pattern formation sheet is used for forming a pattern on a substrate with a thermal transfer printer (see Japanese Patent Laid-Open Publication No. 8-337042).

By the way, in debugging work for a trial circuit board and so forth, signal lines are confirmed one by one before connection of the trial circuit board and a peripheral device in order to prevent improper connection. Such confirmation is one of factors causing the delay of the development process. Meanwhile, the printed circuit board is downsized in response to desire of market requesting reduction of a space of the product. In addition, wiring density of the printed circuit board increases. Thus, visibility of the printed circuit board lowers. Consequently, the above-mentioned factor greatly affects the development process.

The above-noted Publication Nos. 2004-186630 and 8-337042 propose the methods for producing the printed circuit board wherein the producing period is shortened and the production cost is lowered. However, in these Publications, it is not taken into consideration that the visibility of the printed circuit board lowers in accordance with the increment of the wiring density of the printed circuit board.

### SUMMARY OF THE INVENTION

In view of the foregoing, it is a primary object of the present invention to provide a printed circuit board which is adapted to be produced in a short period.

It is a second object of the present invention to provide a printed circuit board of which production cost is low.

It is a third object of the present invention to provide a printed circuit board having excellent visibility.

It is a fourth object of the present invention to provide a method for producing the above-mentioned printed circuit board.

In order to achieve the above and other objects, the printed circuit board according to the present invention comprises wiring patterns and a substrate on which the wiring patterns are formed to carry circuit signals flowing in an electronic circuit. The wiring patterns are formed so as to have different colors in accordance with sorts of the circuit signals.

In the method for producing the printed circuit board, the wiring patterns are formed on the substrate by using conductive coloring materials, which have different colors, in accordance with the circuit signals.

The printed circuit board having this kind of the colored patterns possesses high visibility. Although it is possible to produce such a printed circuit board by a conventional method of screen printing and so forth, it is preferable that printing is performed by means of a printer having simplicity of producing. A printing manner of the printer to be used for producing the printed circuit board is not especially limited. However, it is preferable to use an ink-jet printer and a thermal transfer printer, which are versatile and easily obtainable. The printed circuit board having high visibility can be easily produced by loading a conductive ink and a conductive-ink ribbon into the ink-jet printer and the thermal transfer printer.

According to the present invention, it is possible to grasp the sort of the signal, which is carried through the wiring pattern, from the color of the wiring pattern. At the same time, the wiring pattern carrying the other signal is easily distinguished. Since the printed circuit board has high visibility, it is possible to reduce erroneous recognition of the signal in debugging work of a trial printed circuit board. Moreover, it is also possible to reduce improper connection in operations for assembling and connecting the printed circuit boards. Consequently, a period to be taken for these operations may be shortened.

By adopting the present invention to production of the printed circuit board, it is possible to easily and inexpensively produce the printed circuit board. It is also possible to easily deal with changes, which concern a shape of the printed circuit board and specification of the electronic circuit, during a development process.

### BRIEF DESCRIPTION OF THE DRAWINGS

FIG. 1 is an illustration showing a process in which an FPC having colored patterns is produced by a thermal transfer printer;

FIG. 2 is an enlarged plane view showing a joint portion of the FPC and a PCB;

FIG. 3 is a section view taken along III-III line of FIG. 2; and

FIG. 4 is a perspective view schematically showing an ink-jet printer which is capable of producing the FPC having the colored pattern by means of printing.

### DESCRIPTION OF THE PREFERRED EMBODIMENTS

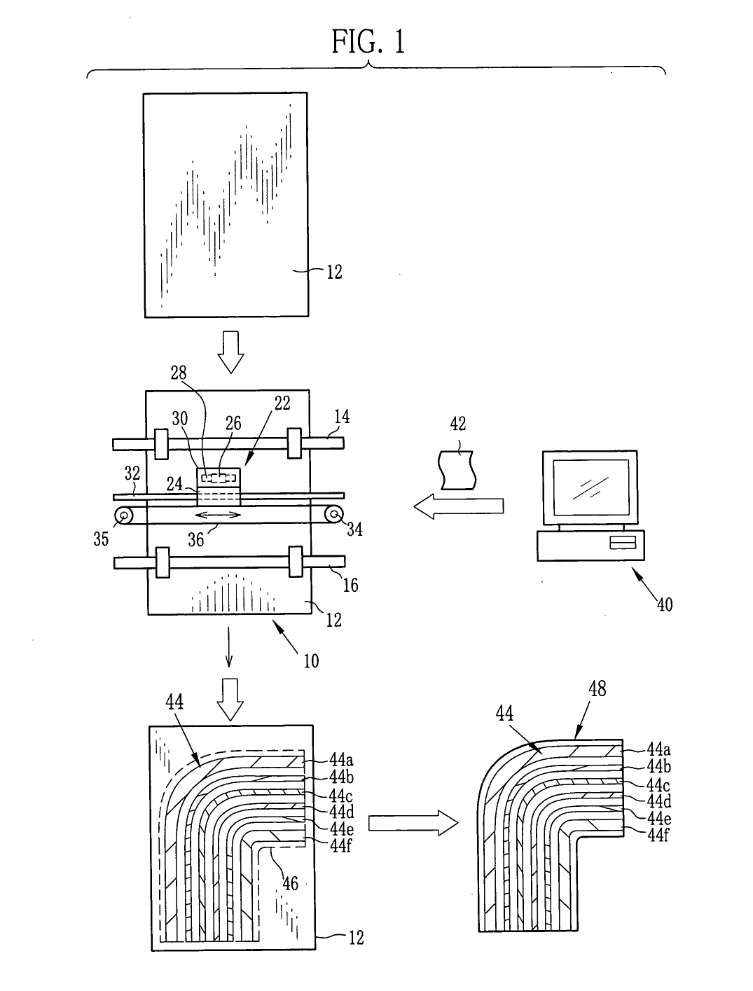

A first embodiment of the present invention is described below. A flexible substrate 12 is set to a paper feed port of a thermal transfer printer 10 shown in FIG. 1. The flexible substrate 12 is drawn from the paper feed port by a paper roller pair 14 and passes through a carrying roller pair 16. A sensor for detecting an anterior end of the substrate 12 is disposed at a downstream side of the carrying roller pair 16. Upon detecting the anterior end of the flexible substrate 12, a detection signal is sent to a system controller built in the thermal transfer printer 10. In response to receipt of the anterior-end detection signal, the system controller shifts a pinch roller of the carrying roller pair 16 to nip the flexible substrate 12.

The paper roller pair 14 and the carrying roller pair 16 are driven by a motor. While printing is performed, the carrying roller pair 16 is rotated in a forward direction so as to intermittently carry the flexible substrate 12 in a feeding direction every predetermined length. During the intermittent feed, a head portion 22 reciprocates in a scanning direction to perform sequential recording.

The head portion 22 comprises a carriage 24 and a thermal head 26 held by the carriage 24. A cassette 30 containing a conductive-color-ink ribbon 28 is loaded in the carriage 24 in an exchangeable manner. A guide shaft 32 passing through the carriage 24 extends in the scanning direction. A part of the carriage 24 is joined to a belt 36 supported by a pair of pulleys 34 and 35.

The ink ribbon 28 is coated with conductive coloring materials of cyan, magenta and yellow such as a normal ink ribbon used for a color printer. The conductive coloring material is composed of conventional color-printer ink and conductive powder of metal powder, metal-oxide powder and so forth.

Next, a producing method for the printed circuit board is described below. First of all, the flexible substrate 12 is set to the paper feed port of the thermal transfer printer 10. When the thermal transfer printer 10 has received print instruction, the thermal transfer printer 10 reads out pattern defining data 42 from a pattern-defining-data creating device 40, which is a computer having a function for designing a pattern layout. On the basis of the pattern defining data 42, colored patterns 44 are formed on the flexible substrate 12. Lastly, a cutoff line 46 surrounding the colored patterns 44 is cut to produce an FPC 48. Incidentally, both ends of the FPC 48 are treated so as to have a strength enabling a fit to a connector. For instance, mounting of a reinforcement member, coating of hardening agent, and overprinting are performed for both ends of the FPC 48.

The pattern defining data 42 is composed of pattern arrangement data which is necessary for forming the colored patterns 44, and pattern color data by which a different pattern color is defined in accordance with a sort of a circuit signal passing the pattern. The pattern arrangement data contains definition information concerning pattern geometry, dimensions, arrangement position and so forth, which are necessary for forming the patterns. The pattern arrangement data is equivalent to that conventionally used in a computer and so forth having a function for designing a layout. Meanwhile, the pattern color data includes definition data for relating the sorts of the circuit signals and the pattern colors. As to the respective pattern colors, a different color is defined in accordance with the sort of the circuit signal passing the pattern.

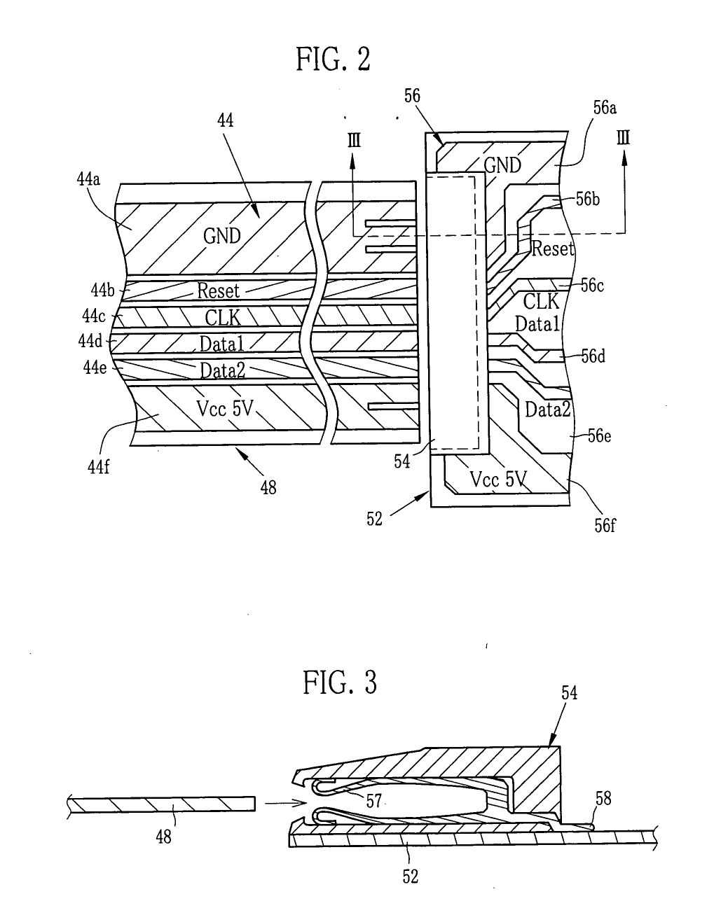

FIG. 2 is an enlarged view of a joint portion where the FPC 48 is connected to a connector 54 of a PCB 52. FIG. 3 is a section view taken along III-III line of FIG. 2. On the basis of pattern color data identical with that of the above-described FPC 48, colored patterns 56 of the PCB 52 are colored in different colors in accordance with sorts of electric signals passing through them. The colored patterns 44 and 56 of this embodiment are formed on the basis of the pattern color data, and are composed of black wiring patterns 44a and 56a representing a ground pattern, blue wiring patterns 44b and 56b representing a reset signal pattern, yellow wiring patterns 44c and 56c representing a clock signal pattern, green wiring patterns 44d and 56d representing a data-one signal pattern, brown wiring patterns 44e and 56e representing a data-two signal pattern, and red wiring patterns 44f and 56f representing a Vcc-5V pattern. In this embodiment, there are only two sorts of the data lines. However, when there are three or more sorts of the data lines, the respective data lines may be colored in different colors relative to the other patterns. Moreover, a name or an abbreviated name of the signal line for electrifying the pattern is written on the pattern or near the pattern. In this embodiment, “GND” representing the ground pattern is written on the black wiring patterns 44a and 56a. Incidentally, it is preferable that characters used for this indication is colored in the same color with the corresponding wiring pattern. In particular, when the characters are written near the corresponding wiring pattern, it is preferable that the characters have a color identical with that of the corresponding wiring pattern and also have higher density in comparison with that thereof. When the characters are written on the wiring pattern, it is preferable that the characters have a color identical with that of the current wiring pattern and also have higher density in comparison with that thereof.

Next, an operation of this embodiment is described below. Such as shown in FIGS. 2 and 3, the FPC 48 is inserted into the connector 54 of the PCB 52 so as to connect the colored pattern 44 of the FPC 48 to the same-color pattern of the PCB 52. By this inserting operation, the black wiring pattern 44a of the FPC 48 is connected to a lead 58, which connects to the black wiring pattern 56a of the PCB 52, via a contact brush 57. The patterns of the FPC 48 and PCB 52 through which the same circuit signal passes are colored in the same color. Thus, it is possible to properly connect the FPC 48 and PCB 52 by joining the same-color patterns. It is unnecessary to perform an operation for confirming a shape of a fitting surface and a small pin mark, although this confirming operation is performed when conventional printed circuit boards are connected. In virtue of this, a time to be taken for the connecting operation is shortened. Meanwhile, a check with eyes is easily performed after connecting the printed circuit boards, and it is possible to prevent the printed circuit boards from working in a state of improper connection. Thus, damaging the printed circuit board and the peripheral device may be avoided.

On the patterns of the FPC 48 and the PCB 52 or near the patterns thereof, the signal-line name having the same color with the pattern is indicated. In virtue of this, it is possible to easily grasp the respective patterns arranged on the printed circuit boards when examinations of a trial printed circuit board, EMI prevention and so forth are performed. Thus, it is possible to shorten a period to be taken for arranging the components, which are added and altered due to a change of specification. Moreover, a period to be taken for examining the EMI prevention may be also shortened.

In the above-described method for producing the printed circuit board having high visibility, it is unnecessary to make a mechanical and to paste cooper foil similarly to printing of the conventional printer. Thus, production equipment for the printed circuit board becomes small, and it is possible to inexpensively produce the printed circuit board in a short period. Accordingly, it becomes possible to easily deal with the change of the specification so that the delay of the development process to be caused by the change of the specification is minimized. Further, since the substrate of the printed circuit board is not restricted on condition that the substrate is printable with a printer, it is possible to produce various printed circuit boards.

As will be understood from the above, the patterns are formed on the printed circuit board by using the conductive-color-ink ribbon and the thermal transfer printer, and it is possible to inexpensively produce the printed circuit board in a short time. In addition, the printed circuit board has high visibility so that it is possible to grasp the pattern arrangement and the sorts of signals on the printed circuit board. Thus, it is possible to easily deal with the change of the specification during the development process. Consequently, it is possible to improve the efficiency of examination work and debugging work.

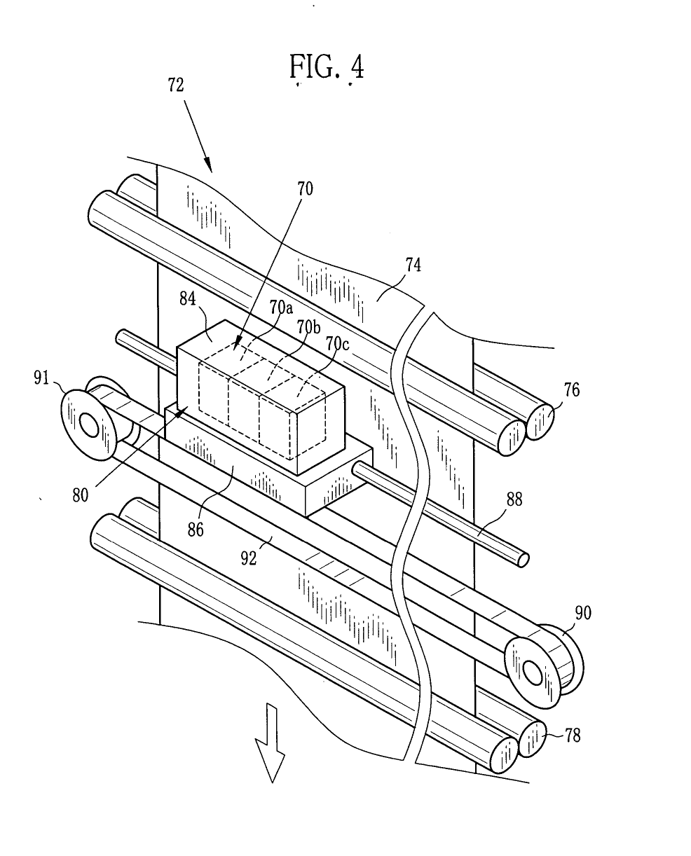

In the above embodiment, the colored pattern 44 is formed on the flexible substrate 12 by using the thermal transfer printer 10 loaded with the conductive-color-ink ribbon 28. By virtue of this, the printed circuit board having high visibility is produced. However, this is not exclusive. It is possible to obtain similar advantage by using an ink-jet printer 72 shown in FIG. 4. The ink-jet printer 72 employs a conductive color ink 70 including conductive coloring material. The ink-jet printer 72 comprises a paper roller pair 76, a carrying roller pair 78, an ink tank 84, an ink injector, a carriage 86, a guide shaft 88, pulleys 90 and 91, and a belt 92. The paper roller pair 76 and the carrying roller pair 78 carry a flexible substrate 74 in the feeding direction to print a colored pattern thereon. The ink tank 84 and the ink injector constitute a head unit 80. The carriage 86 reciprocates the head unit 80 in the scanning direction to perform sequential recording. Conductive-color inks 70a, 70b and 70c of three colors of cyan, magenta and yellow are individually contained in the ink tank 84 as conductive coloring materials.

In the above embodiments, the serial printer is used. However, this is not exclusive. Similar advantage may be obtained even if a line printer is used.

In the foregoing embodiment, the colored patterns 44 and 56 are formed by using the printer. However, this is not exclusive. The colored pattern may be formed by another application method utilizing conductive ink pens having different colors.

In the foregoing embodiment, the colored pattern 44 is printed on the flexible substrate 12 by using the thermal transfer printer 10 loaded with the conductive-color ink ribbon 28. However, this is not exclusive. Similar advantage may be obtained by coloring a pattern formed on the substrate beforehand.

In the foregoing embodiment, the conductive material of the different color is used for the respective patterns. Instead of this, the respective patterns may be colored in desired colors after these patterns have been formed by using the conductive material of the sole color. For instance, wiring patterns are printed with the conductive material of the sole color, which is white, silver or the like. After that, a color coding pattern is printed on the wiring pattern for the purpose of distinguishing the signal of the same circuit. Also in this case, similar advantage may be obtained, although it is necessary to perform printing by two times.

In the foregoing embodiment, the thermal transfer printer is loaded with the conductive-color ink ribbon and printing is performed on the substrate to form the pattern. In addition, an insulating-ink ribbon may be used at the same time to form an area, which has isolation, on the substrate.

In the foregoing embodiment, the thermal transfer printer is described. However, this printer is not exclusive. A substrate having or losing conductivity by application of heat may be used. In this case, a desired region of the substrate is heated by a thermal head to form a pattern or an insulating portion so that an FPC is produced.

In the foregoing embodiment, the pattern arrangement data includes the shape of the pattern, the dimension thereof, and the definition information of the arrangement position thereof, which are necessary for forming the pattern. Moreover, the pattern color data is defined so as to relate the sort of each circuit signal to the pattern color. However, instead of this kind of the data, drawing software may be used for example to draw simple patterns. In this case, it is possible to obtain similar advantage by designating different colors to the respective patterns.

In the foregoing embodiment, the described conductive-color ink ribbon employs three colors of cyan, magenta and yellow. However, this is not exclusive. Similar advantage may be obtained by indicating colors combined with other colors of black, while and so forth.

In the foregoing embodiment, each pattern is colored in the sole color. However, this is not exclusive. The pattern may be colored in a stripe shape and so forth utilizing plural colors so as to be distinguishable from other patterns. Moreover, it is possible to distinguish the patterns on the basis of the colored pattern and the uncolored pattern.

In the foregoing embodiment, printing is performed on one surface of the substrate to produce the single-sided FPC. However, this is not exclusive. It is possible to produce a double-sided FPC by performing printing on both surfaces of the substrate. Moreover, it is possible to form a plurality of electrode layers and insulating layers by performing overprinting with a conductive-color ink ribbon and an insulating-color ink ribbon. Consequently, it is possible to produce a multi-layer FPC and to improve shield effect of the FPC.

As to the forgoing embodiment, it is possible to make the respective patterns have a desired thickness by performing overprinting on the pattern.

In the present invention, the type of the substrate is not restricted on condition that the substrate is printable. For instance, it is possible to form an electronic circuit pattern on an inflammable material of a paper and so forth. In this case, a waste material may be reduced.

The FPC is adapted to have strength by using a reinforcement material and a hardening material, and by performing overprinting. At this time, it is possible to insert the FPC into a connector. Meanwhile, when the used substrate comprises high-hardness synthetic resin used for a compact disk and so forth, durability of the printed circuit board is improved.

When the present invention is applied to the substrate of heat-resistant material of polyimide and so forth, it is possible to produce a printed circuit board on which soldering can be directly performed.

By applying the present invention to an adhesive material of a seal paper, an adhesive tape and so forth, it is possible to easily produce an EMI-countermeasure member of a shield tape and so forth. Moreover, by performing printing for the entire substrate and by cutting off the substrate in a desired shape, it is possible to easily produce a shield member having a freely determined shape.

By using a device including a sensor for distinguishing the colored pattern of the printed circuit board and the color of the pattern, it is possible to utilize the colored pattern for checking the finished product of the printed circuit board and for positioning the printed circuit boards to be connected to each other. Thus, quality for checking the finished product of the printed circuit board is improved, and efficiency of an assembling operation is improved.

When connecting the printed circuit boards produced on the basis of the same pattern color data, a time to be taken for a connecting operation thereof is shortened and it is possible to prevent improper connection. In view of this, it is preferable that the pattern color data is shared as a tool for producing other printed circuit boards. Meanwhile, the color of each wiring pattern may correspond to a color of a wire cable used for connection. In this case, improper connection is easily recognized when the color of the wire cable to be connected does not coincide with the color of the wiring pattern. Thus, the improper connection is prevented.

In the foregoing embodiment, the name of the signal line for electrifying the pattern is indicated on or near the pattern by the letters having the same color with the pattern. However, this is not exclusive. Similar advantage may be obtained by indicating letters and indicia, which have the same color with the corresponding pattern, within a margin of the printed circuit board.

Although the present invention has been fully described by way of the preferred embodiments thereof with reference to the accompanying drawings, various changes and modifications will be apparent to those having skill in this field. Therefore, unless otherwise these changes and modifications depart from the scope of the present invention, they should be construed as included therein.

What is claimed is:

1. A printed circuit board for constituting an electronic circuit, comprising:
a plurality of wiring patterns for carrying circuit signals flowing in said electronic circuit, said wiring patterns having different colors in accordance with sorts of said circuit signals; and
a substrate on which said wiring patterns having the different colors are formed.

2. A printed circuit board according to claim 1, wherein said wiring patterns having the different colors are formed by a printer which prints conductive materials of different colors on said substrate.

3. A printed circuit board according to claim 2, wherein said printer is either of an ink-jet printer and a thermal transfer printer.

4. A printed circuit board according to claim 2, wherein said conductive materials are conductive inks of cyan, magenta and yellow.

5. A printed circuit board according to claim 1, further including characters representing the sort of said circuit signal, said characters being indicated on either of the corresponding wiring pattern and the vicinity thereof.

6. A printed circuit board according to claim 5, wherein said wiring patterns and said characters are formed by a printer which prints conductive materials of different colors on said substrate.

7. A printed circuit board according to claim 5, wherein said characters have a color identical with that of the corresponding wiring pattern and have higher density in comparison with that thereof when said characters are recorded on the vicinity of the wiring pattern.

8. A printed circuit board according to claim 5, wherein said characters have a color identical with that of the wiring pattern and have higher density in comparison with that thereof when said characters are recorded on the wiring pattern.

9. A printed circuit board according to claim 1, wherein said substrate has flexibility.

10. A producing method for a printed circuit board constituting an electronic circuit, said printed circuit board comprising a plurality of wiring patterns for carrying circuit signals flowing in said electronic circuit, and a substrate on which said wiring patterns are formed, said producing method comprising the step of:
applying conductive materials of different colors to print said wiring patterns on said substrate in different colors in accordance with sorts of said circuit signals.

11. A producing method according to claim 10, wherein said wiring patterns are printed by either of an ink-jet printer and a thermal transfer printer.

12. A producing method according to claim 11, wherein said conductive materials are conductive inks of cyan, magenta and yellow.

13. A producing method according to claim 10, further comprising the step of:
indicating characters, which represent the sort of said circuit signal, on either of the corresponding wiring pattern and the vicinity thereof.

14. A producing method according to claim 13, wherein said wiring patterns and said characters are formed by a printer which prints conductive materials of different colors on said substrate.

15. A producing method according to claim 13, wherein said characters have a color identical with that of the corresponding wiring pattern and have higher density in comparison with that thereof when said characters are recorded on the vicinity of the wiring pattern.

16. A producing method according to claim 13, wherein said characters have a color identical with that of the wiring pattern and have higher density in comparison with that thereof when said characters are recorded on the wiring pattern.

17. A producing method according to claim 10, further comprising the step of:
cutting off a contour of said wiring patterns from said substrate.

18. A producing method according to claim 10, wherein said substrate has flexibility.
